(19) United States
(12) Patent Application Publication
(10) Pub. No.: US 2002/0074481 A1
(43) Pub. Date: Jun. 20, 2002

(54) Dual-mode CMOS integrated imager

(76) Inventors: R. Daniel McGrath, Andover, MA (US); Bennett H. Rockney, Westford, MA (US); Vincent S. Clark, Arlington, MA (US); Surinderjit S. Dhaliwal, Laguna Niguel, CA (US)

Correspondence Address: LAW OFFICE OF THOMAS SCHNECK, P.O. BOX 2-E, SAN JOSE, CA, 95109-0005, US

(21) Appl. No.: 09/872,209

(22) Filed: Jun. 1, 2001

Related U.S. Application Data
(60) Provisional application No. 60/209,011, filed on Jun. 1, 2000.

(51) Int. Cl. H01L 27/00

(52) U.S. Cl. 250/208.1

(57) ABSTRACT

A CMOS integrated imager system formed on a single IC having a first mode in which the system operates using on-chip logic to generate complex timing on-chip and to use that timing for operation and also having a second mode of operation in which the on-chip logic is bypassed and an external timing system is used.

### CROSS-REFERENCE TO RELATED APPLICATION

This application claims priority from U.S. provisional application No. 60/209,011, filed Jun. 1, 2000.

### TECHNICAL FIELD

The present invention relates to a single chip imaging system and more specifically to an imaging system that can operate with timing signals generated on-chip or with timing signals received from an external source.

### BACKGROUND ART

Imaging systems receive an image obtained from a video camera, scanner or other device that captures and stores still images as digital data, and converts the image to a graphical image or data that represents a two-dimensional scene. A digital image is composed of pixels arranged in a rectangular array with a certain height and width. Each pixel may consist of one or more bits of information, representing the brightness of the image at that point and possibly including color information encoded as RGB (red, green, blue) triples. Imaging systems have a wide variety of applications in many fields.

In designing the imaging systems of the prior art, attempts have been made to design systems that minimize noise, thereby producing an output that closely follows the image, and that minimize the overall size of the device. Additionally, attempts have been made to make imaging systems that are compatible with CMOS technology in order to reduce the overall power dissipated in the system by being able to have the controlling circuitry made from CMOS or some other low power-dissipating logic family. For example, U.S. Pat. No. 5,841,126 to Fossum et al. discloses an imaging system in which the controller electronics are integrated onto the same substrate as the photosensitive element. The Fossum et al. device is compatible with CMOS and has reduced size and power dissipation due to the control system elements, such as integration, timing, A/D conversion, etc . . . , being integrated on the same substrate as the photosensitive element.

The inventors of the present invention have identified a need by some users of imaging systems to have a simplified system that requires a reduced number of signals to control the images. However, other users prefer to provide their own timing to the imaging system or need the imaging system to be compatible with an external FPGA or other device that already includes clock and timing control. Therefore, it is desirable to produce an imaging device that can operate under two different timing protocols.

In the prior art, it is known to have different timing protocols for a particular signal. For example, many patents disclose having read signals of two different lengths, for example, U.S. Pat. No. 5,394,541 to Chesley et al.; U.S. Pat. No. 5,495,594 to MacKenna et al.; U.S. Pat. No. 5,587,961 to Wright et al.; and U.S. Pat. No. 5,615,358 to Vogley. However, these patents deal with altering a particular timing signal, rather than providing the user with the choice of using either an external timing system or a timing system generated entirely within the imaging device.

Historically, imaging systems have been assemblies of separate components and have had a digital section and an analog section. To achieve maximum performance and to differentiate their products, developers have optimized the timing and biases controlling the analog section (e.g., the image array, the signal chain, the analog-to-digital converter). There is a value in allowing similar access for integrated systems.

It is the object of the present invention to provide a CMOS integrated imager system that is operable in either a first mode using an internal timing element or in a second mode using an external timing element.

It is a further object of the invention to provide an imager system having an internal timing element that reduces the number of signals required to control the imager in an end-use application.

### SUMMARY OF THE INVENTION

The above objects have been met by a CMOS integrated imager system that uses on-chip logic to generate complex timing on-chip. The imager system has an interface for receiving data, address and control signals, including a mode signal for setting the system either to operate using the on-chip timing system or to bypass the on-chip timing system and operate using an external timing system. The imager of the present invention provides high quality images using an easy interface and simple operation in order to reduce time and cost. The invention also provides the user the option to take control of every aspect of scan timing externally in an FPGA if the user requires the modes of operation to be extended for advanced imaging.

### BRIEF DESCRIPTION OF THE DRAWINGS

FIG. 1 is a block diagram of the overall imager system of the present invention showing both internal and external timing options.

FIG. 2 is a block diagram of the imager system of the present invention.

FIG. 3 is a block diagram of an alternate embodiment of the imager system of FIG. 2.

FIG. 4 is a block diagram of the configuration of the imager system of FIG. 2 in a first mode of operation.

FIG. 5 is a block diagram of the configuration of the imager system of FIG. 2 in a second mode of operation.

FIG. 6 is a block diagram of the image sensor array of the imager system of FIG. 2.

FIG. 7 is a timing diagram of the start pattern of row read and row blanking operations in the first mode of operation.

FIG. 8A and 8B are timing diagrams showing a short first frame of image.

FIG. 9 is a timing diagram showing a row blanking strobe.

FIG. 10 is a timing diagram showing a row read strobe.

FIG. 11 is a timing diagram showing the end of a row read.

FIG. 12 is a timing diagram showing the end of a frame.

FIG. 13 is an electrical schematic of a pixel array used in the imager system of FIG. 2.

FIG. 14 is a timing diagram for the pixel array shown in FIG. 13.

### BEST MODE FOR CARRYING OUT THE INVENTION

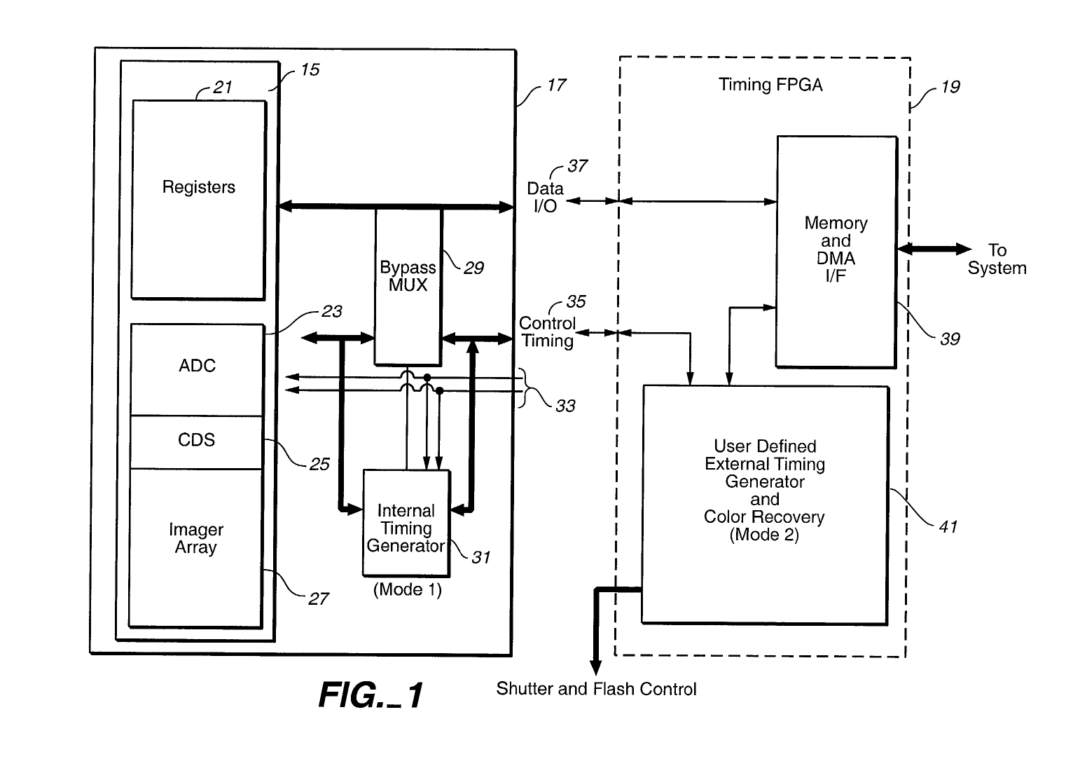

With reference to FIG. 1, the imager system of the present invention is shown with both internal and external timing options. The imager system 17 includes an imager acquisition die 15 having a plurality of registers 21, an analog-to-digital conversion block 23, a correlated double sampling (CDS) block 25, and an imager array 27. The imager system 17 has an internal timing generator 31 for generating on-chip timing to the control timing bus 35. The data bus 37 provides data to the registers 21. A bypass multiplexer 29 is connected to the control bus 35 and is used to bypass the internal timing generator 31 in order to use an external timing block 19, which can include a timing field programmable gate array (FPGA). The external timing block 19 is used when the user requires a specialized timing protocol. In this case, the external logic block 19 is interfaced with the imager 17 utilizing all of the device pins and the external timing block 19 will then provide all of the timing and control signals to the imager 17. The external logic block 19 includes an external timing generator and color recovery block 41, which is defined by the user, and also includes a memory and DMA interface block 39. The imager 17 recognizes the two different timing modes by inspection of two control lines 33 receiving a mode signal. The control lines 33 are inspected and will operate using internal timing unless one or both of the control lines receive a signal having a logic level “1” value. The pins have internal pull-down resistors and will automatically force the device to internal timing if left unconnected or tied to a voltage of zero volts.

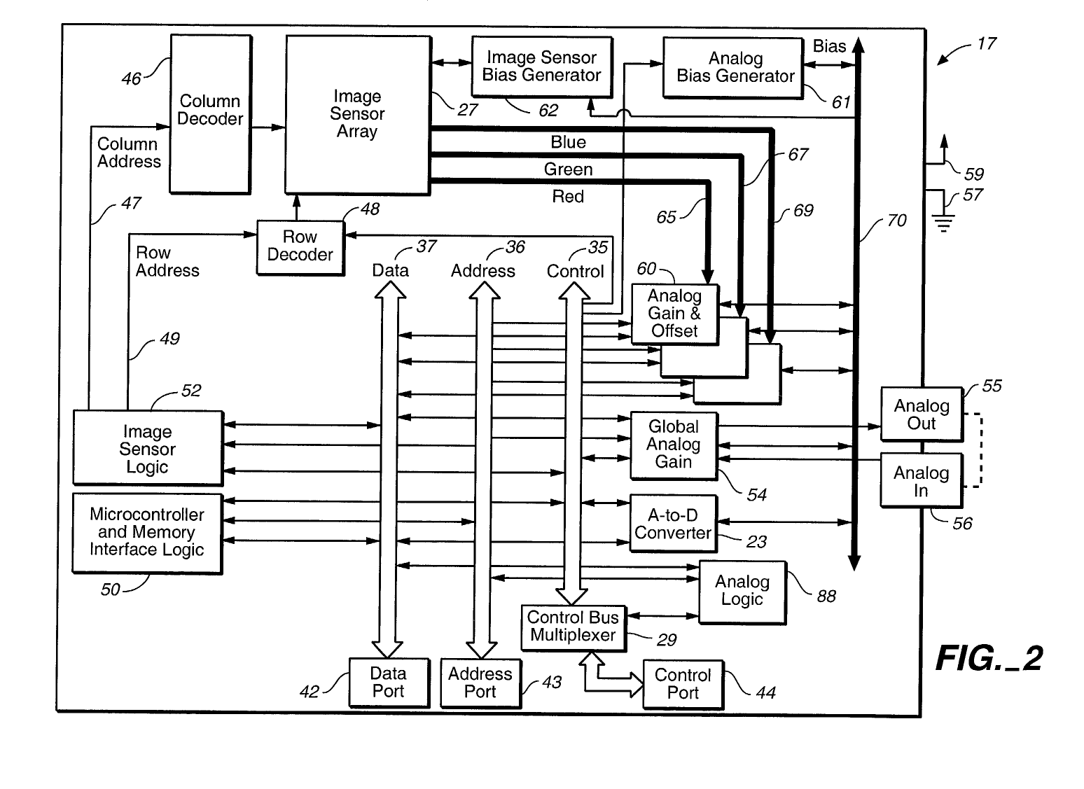

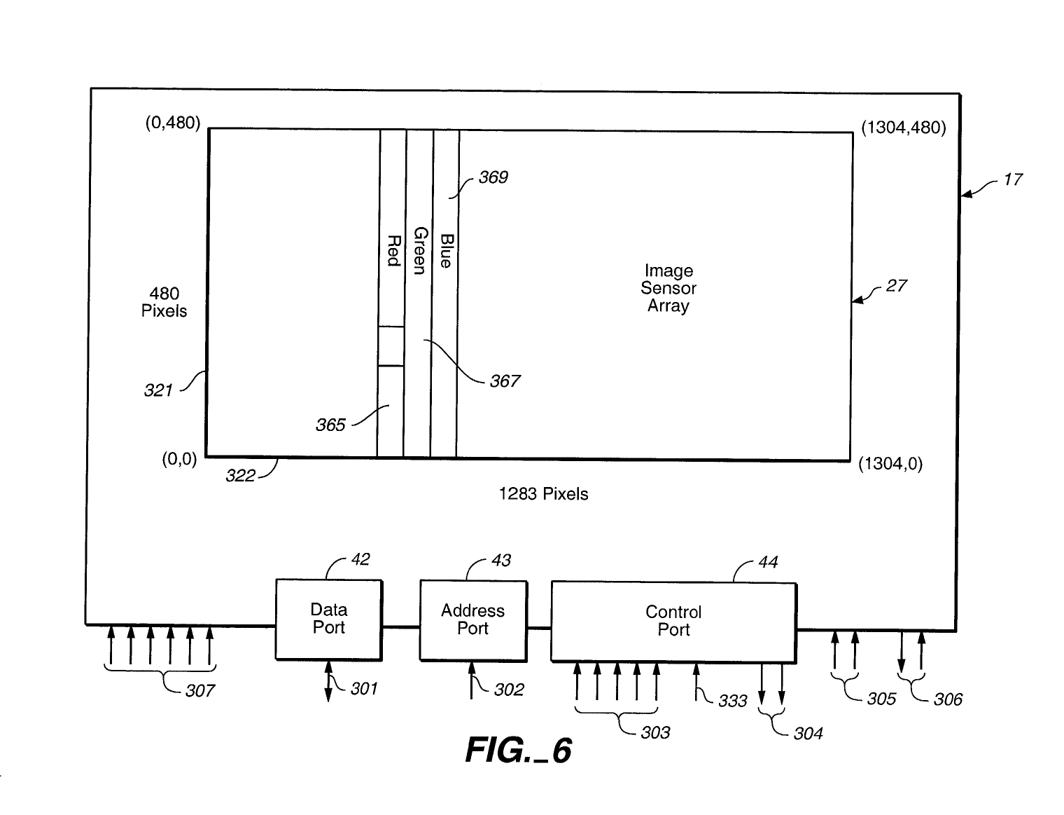

With reference to FIG. 2, a detailed block diagram of the imager system 17 is shown. The imager system 17 has an interface consisting of a data port 42, an address port 43, and a control port 44. The data port receives external data and the data is supplied to the data bus 37. Address information is received at the address port 43 and is supplied to the address bus 36. Control signals are received at the control port 44 and are supplied to control bus 35. Analog control signals are generated by the analog control block 88 and are supplied to the data 37, address 36 and control 35 buses. The control bus multiplexer 29 is connected to the control bus 35, as explained above. The control bus multiplexer 29 is used to bypass the internal timing generator when the system is in external timing mode. The control bus multiplexer is controlled externally by signals on one or more control port lines. The imager system 17 includes an image sensor array 27 which is shown in more detail in FIG. 6. With reference to FIG. 6, the image sensor array 27 is a pixel array of 1283 by 480 rectangular active pixels with a high physical fill factor of 43% (with microlenses). A vertical stripe RGB pastel color filter is used with individual column correlated double sampling (CDS) correction circuitry to produce a low level of fixed pattern image noise. There are 1,283 regular pixels, along with 21 dark pixels and one test pixel on the X-axis 322, while there are 480 regular pixels, along with 9 dark pixels and one test pixel, on the Y-axis 321 of the image sensor array. The red 365, green 367 and blue 369 color filters are used to define the pixels.

Referring back to FIG. 2, the image sensor logic block 52 receives signals from the data 37, address 36 and control 35 buses and produces row address 49 and column address 47 signals. The column address signals 47 are input to a column decoder 46 which decodes the address words and latch output for image sensor array 27 column selection. The row address signals 49 are input to the row decoder which decodes the address words for image sensor array 27 row selection. The image sensor logic block 52 provides the counters for generating row and column address signals for region of interest and subsampled read out. It also generates reset and select timing for each row for still and viewfinder mode. A microcontroller and memory interface logic block 50 is also connected to the data 37, address 36, and control 35 buses. The interface logic decodes the address, generates core select signals for register addressing, and also provides power and test mode management. The image sensor array 27 converts the optical images to color separated analog electrical output signals. The sensor array is addressed digitally by row and column as explained above. The three analog signals blue 69, green 67 and red 65 are supplied to an analog gain and offset block 60. The analog gain and offset block 60 provides adjustable offset and gain for the three analog channels and the output of the analog gain and offset block 60 is provided to an analog bias line 70. The global analog gain block 54 provides global gain for the three analog channels and produces the output on the bias line 70. An A/D converter 23 converts the analog signal into digital words.

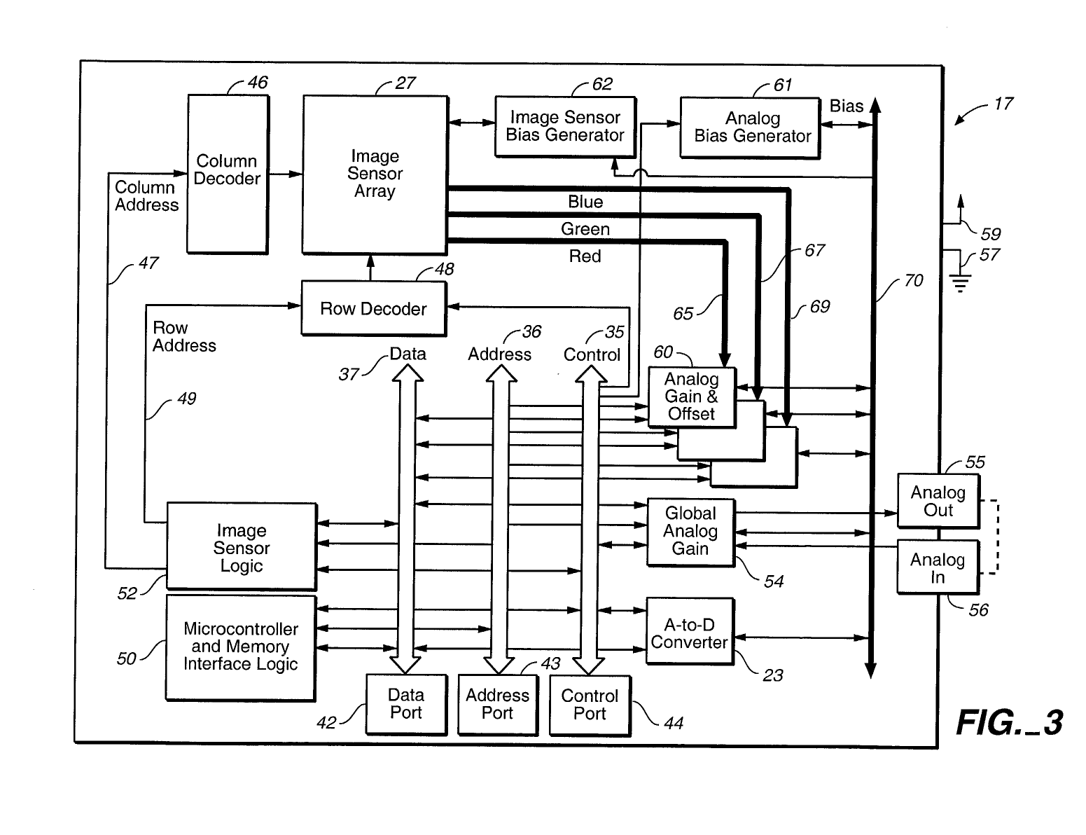

With reference to FIG. 3, an alternate embodiment of the present invention is shown. In the alternate embodiment, all of the analog control signals are provided from an external source through the control port. Therefore, the analog logic block 88, as shown in FIG. 2, is not necessary in this embodiment.

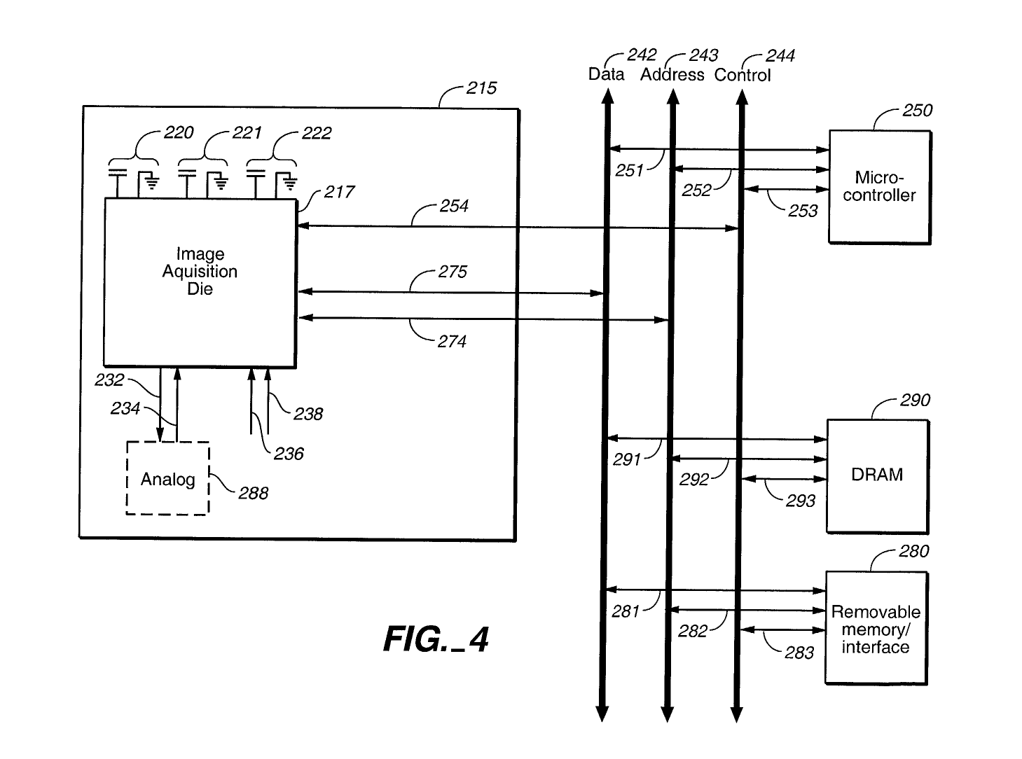

With reference to FIG. 4, the imager system 215 is shown to be configured in a first mode of operation. In the first mode of operation, the system timing is generated on the image acquisition die 217. The system 215 includes the image acquisition die 217, and may include an analog control block 288 which is optionally provided by the user. The image acquisition die 217 receives analog voltage and ground signals 220, digital voltage and ground signals 221, and pad driver voltage and ground signals 222. The image acquisition die is connected to the control bus 244 via signal line 254, and to the data bus 242 via signal line 275, and to the address bus 243 via signal line 274. The analog control block 288 interacts with the image acquisition die via signal lines 232, 234, 236 and 238. The microcontroller 250 is connected to the data, address and control buses via signal lines 251, 252, 253, respectively, and provides system control through register loads and reads, and through an asynchronous interrupt.

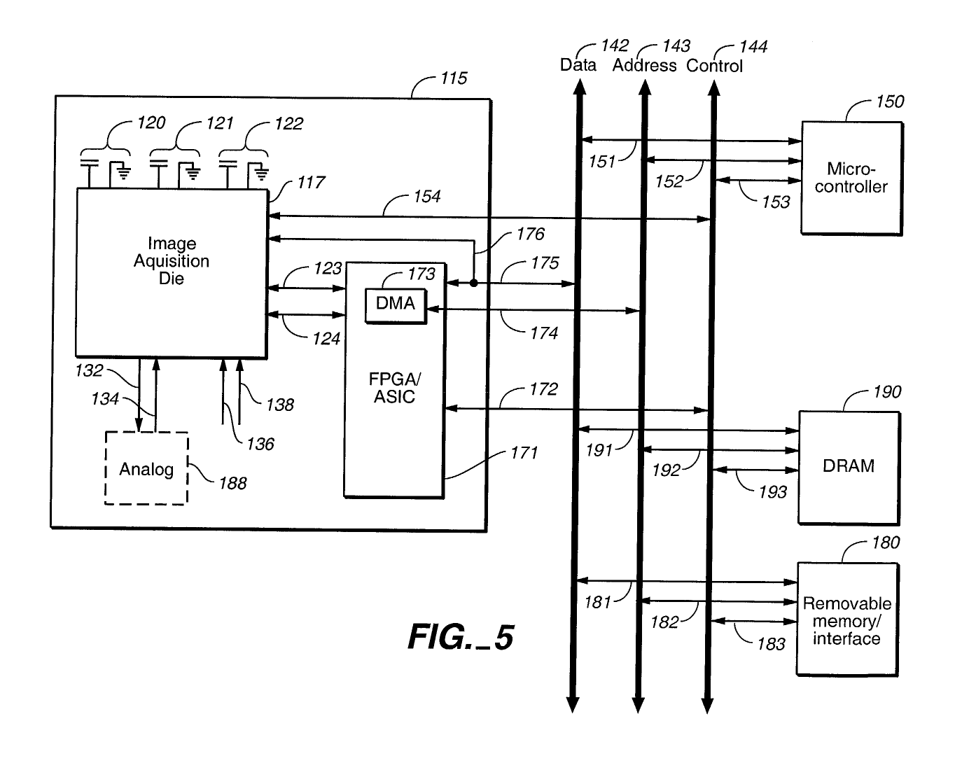

With reference to FIG. 5, the imager system 115 is shown to be configured in a second mode of operation. In the second mode of operation, the system timing is generated by an external timing block including a FPGA/ASIC 171 which contains a DMA control 173. The image acquisition die is connected to the control bus 144 via the line 154 and to the data bus 142 via lines 176 and 175. Signal lines 123 and 124 provide the signals between the image acquisition die 117 and the DMA 173, and the address signals are provided to the address bus 143 via line 174. Otherwise, the system 115 is configured in the same manner as described above with reference to FIG. 4.

With reference to FIG. 6, various signals are input to the interface of the imager system signal. Lines 307 supply the bus voltage and ground signals for the analog, digital and pad signals. The data port 42 receives a ten-bit register value on signal line 301. The address port 43 receives a four-bit register address on signal line 302. The control port 44 receives a plurality of control signals on signal lines 303 including frame reset, row reset, channel convert, chip select, enable column, frame sync, line sync, column clamp, row select, pixel reference, pixel sample, and read, and write signals. One of the control signals is a mode select signal 333 which selects whether the device operates in the first mode or second mode of operation. Signal lines 305 are inputs to the pixel test bias and signal lines 306 are the analog-in and analog-out signals.

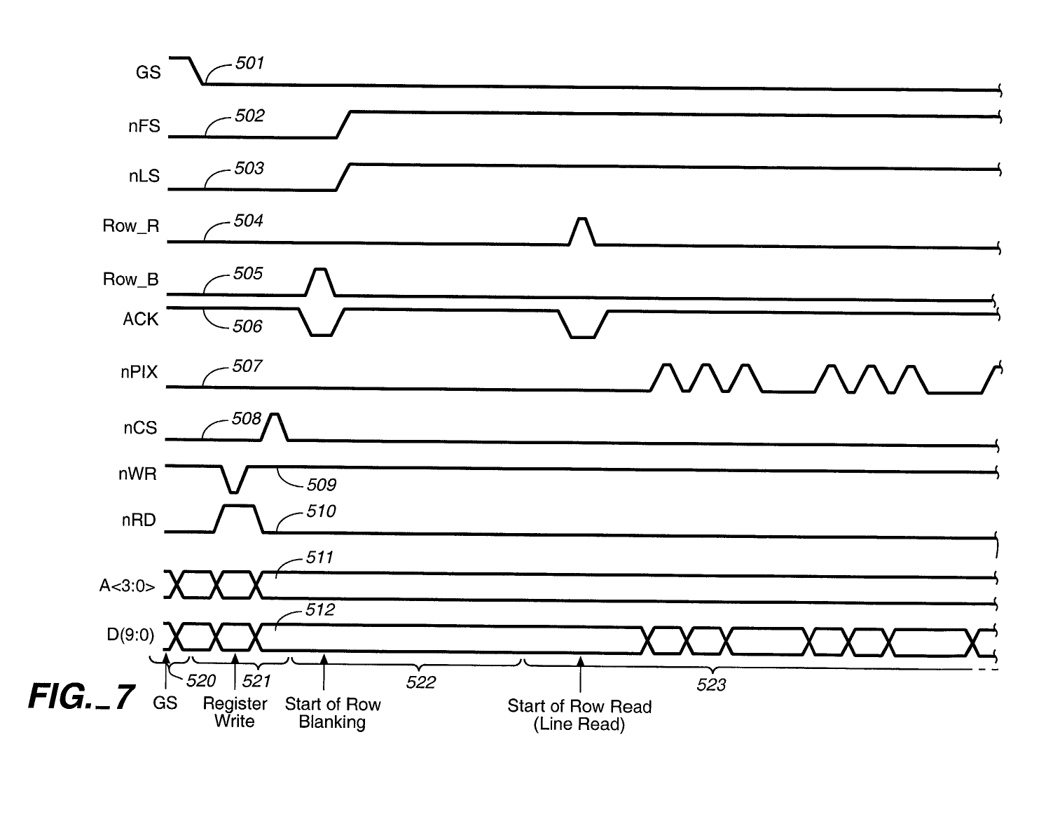

When the imager system is in the first mode of operation, the timing is generated on chip. The internal timing is shown with reference to FIGS. 7-12. Beginning with FIG. 7, the start pattern is shown for the row blanking and row read operations. The row blanking operation causes the imager to process a complete row of image through the CDS block, while the row read operation processes the image out to the data bus. In each of the FIGS. 7-12, the following signals are shown and are defined as follows. Global set (GS) 501 is a signal that sets the registers to default values. Frame sync (nFS) 502 is a digital output signal that indicates the frame read out. Line sync (nLS) 503 is a digital output signal that indicates the line read out. Row read (ROW_R) 504 is a digital input signal that begins the row read operation. Row blanking (ROW_B) 505 is a digital input signal that begins the row blanking process. The acknowledge signal (ACK) 506 is a digital output signal that indicates whether or not the process is busy. The pixel sync (nPIX) 507 signal is a digital output that indicates the pixel read out. A chip select signal (nCS) 508 either permits or prevents any data from being output into a particular data register. The write signal (nWR) 509 is a digital input to indicate the write cycle. The read signal (nRD) 510 is a digital input signal to indicate the read cycle. Also shown are the address register (A) 511 and the data input register (D) 512. The address register 511 receives a four-bit register input while the data register 512 receives 10-bit read/write data values.

Still operation is achieved using an electronic half shutter and would be usually augmented by an external mechanical shutter for high speed exposures. The image sensor logic register is first set to 111111111 and the imager is reset by strobing the frame reset input (not shown) high. The exposure time is determined under external control and can be as short as one acknowledgment cycle or as long as the user requires. After the exposure period, the imager is read out on a line by line basis starting with the lower left hand corner of the area defined in the image sensor logic register. Strobing the row blanking line 505 high causes the imager to process a complete row of image through the CDS block. When this cycle is completed, the imager drops the acknowledgment signal 506 low and is ready to stream data out.

As shown in FIG. 7, during the global set period 520, the global set signal 501 sets the registers to the default value. Then, during period 521, the write signal 509 goes low to write to the data register 512. After the write signal 509 returns to high, the chip select signal is activated 508 and the row blanking signal 505 is activated at the same time as the acknowledge signal 506. This starts the row blanking process 522, as noted above. When the row blanking process is completed, then the row read process 523 begins. The row read signal 504 is asserted high and the imager puts the data on the bus at a maximum rate of one pixel at every two master clock cycles which indicates good data on the falling edge of the (nPIX) 507 signal.

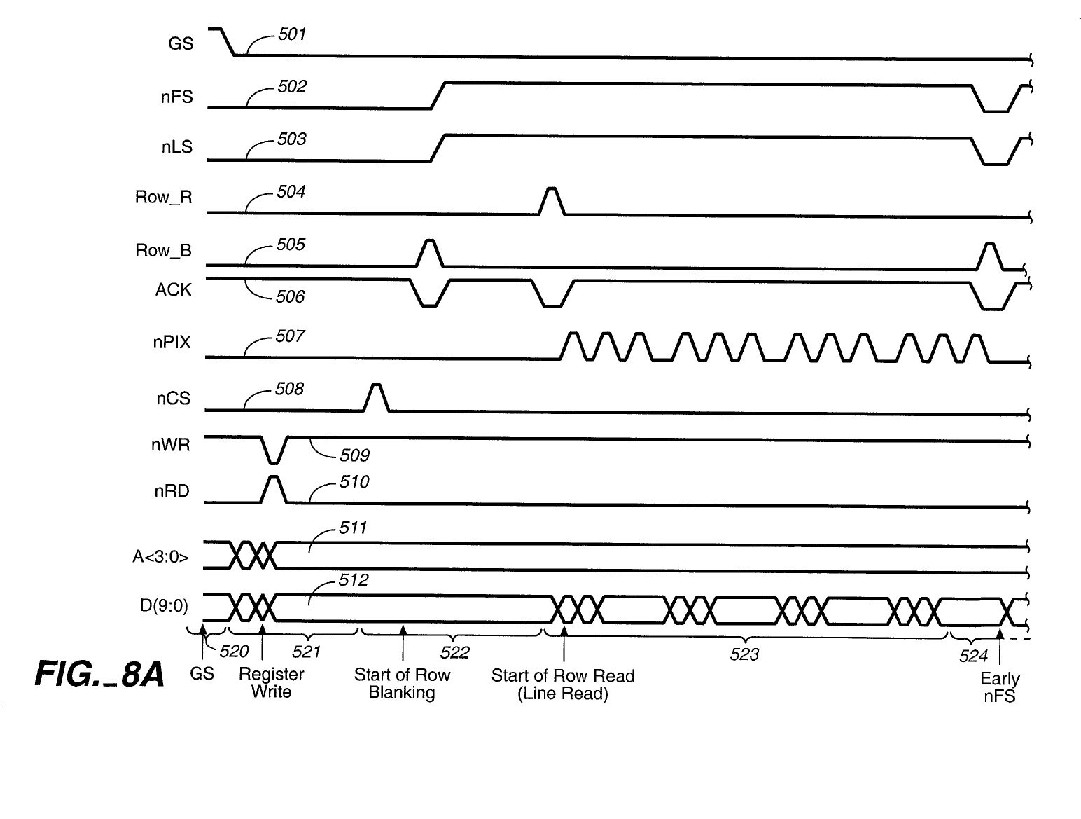

With reference to FIGS. 8A and 8B, the timing diagram for a short first frame of data is shown. The first part of FIG. 8A is the same as that described above with reference to FIG. 7, which describes the signals at the start of the row blanking and row read cycles. At one half of the master clock cycle, following the last falling edge of the nPIX signal 507 for the last pixel in a row, the imager also drops the line sync signal 503 to indicate a line sync. Strobing the row blanking signal 505 again will cause the second row to be read out and so on. After the last line as been read out, the imager also drops the frame sync signal 502 low coincident with the line sync signal 503 to indicate a frame sync. This process is shown with regard to period 524 in FIG. 8A. Then, with reference to FIG. 8B, at period 525, the row read and row blanking repeats for all of the lines and then the frame sync signal (nFS) 502 falls when this process is completed.

Although a mechanical shutter may be used to prevent direct exposure after reading of the image has begun, the pixels will continue to integrate dark current. The readout period, once the shutter is closed, should therefore be kept as short as possible in relation to the exposure time to avoid a brightness gradient down the picture. If this is not possible, due to system or transmission channel constraints, then a simple algorithm can be implemented to correct for it. The next frame exposure is started again by strobing the frame reset signal. Subsequent frames of image will contain full valid data, as the reset and read points will smoothly wrap around the imager. After the latency is determined by the amount of exposure programmed into the exposure register, real image data is available at the output. To receive the data, the user strobes the row read signal after the row blanking signal is acknowledged for each row and latches the data on the falling edge of the pixel signal (nPIX) 507. The user must strobe the row read signal early enough so that the last pixel in a row is output before the next row blanking strobe is applied in order to avoid the data from being curtailed.

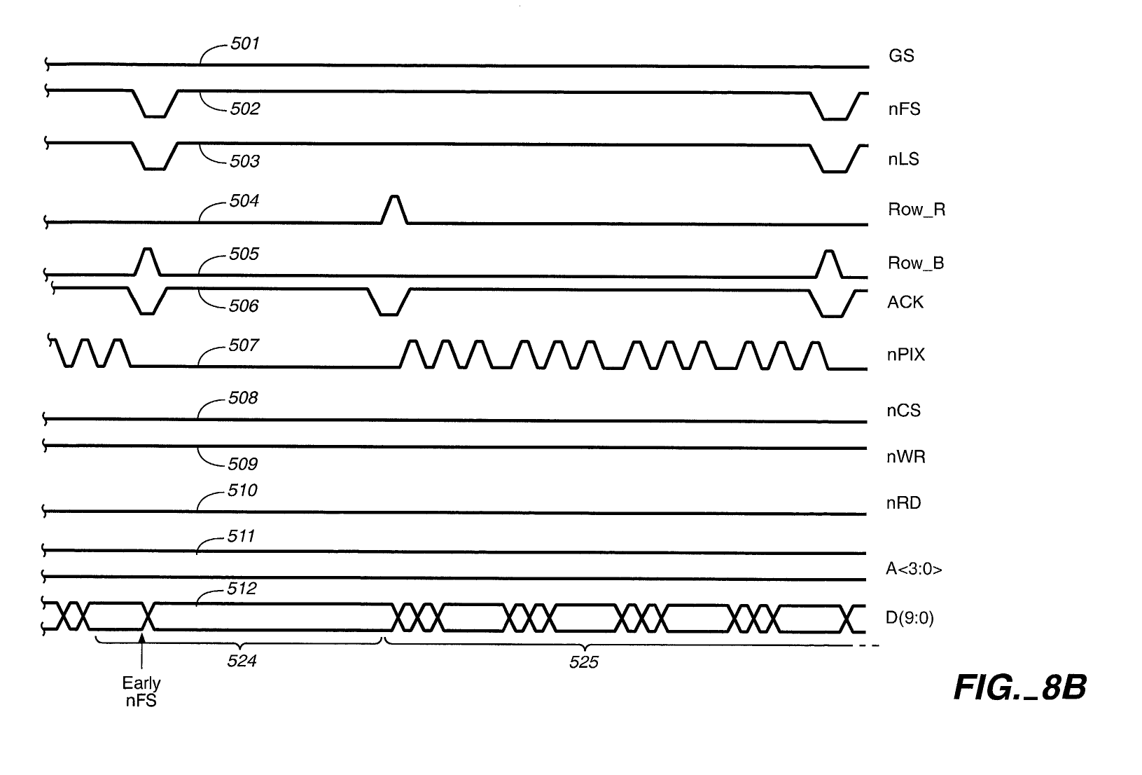

FIG. 9 shows a detailed view of the start of the row blanking process 522. An additional signal, the master clock signal 515 is shown. As shown, the chip select signal 508 is started on the rising edge of the master clock. The start coordinate is loaded into the internal start register and the main counters are reset to the content of the internal start register. On the falling edge of the chip select signal 508, this triggers the register-to-counter transfer. The acknowledgment signal 506 then drops low to indicate that the row blanking process can start, the row blanking signal 505 goes high and then low to start the row blanking procedure. When the acknowledgment signal goes high, this indicates that the internal start machine has finished the last operation of the row blanking.

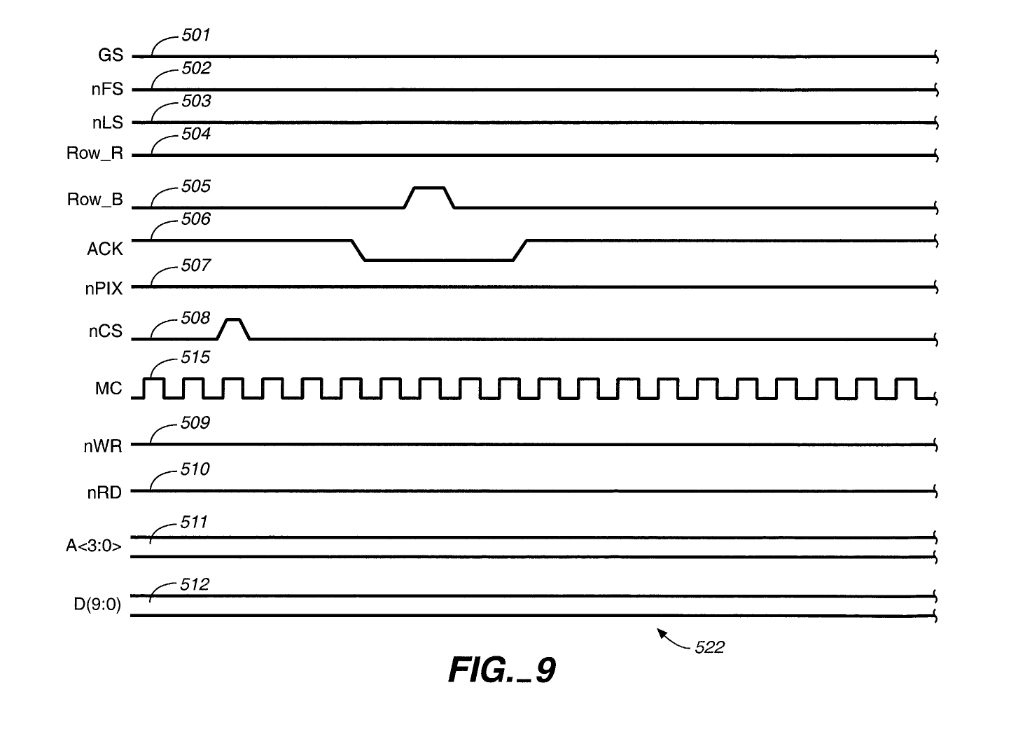

With reference to FIG. 10, the row read strobe 523 is shown. The acknowledgment signal 506 is strobed again to indicate that the row read can start and the row read signal 504 is strobed to begin the row read process. The frame sync and line sync signals go high as the row read process starts. When the nPIX signal 507 is activated, then the data is read out in the data registers, shown to be in the form of red pixels, green pixels and blue pixels.

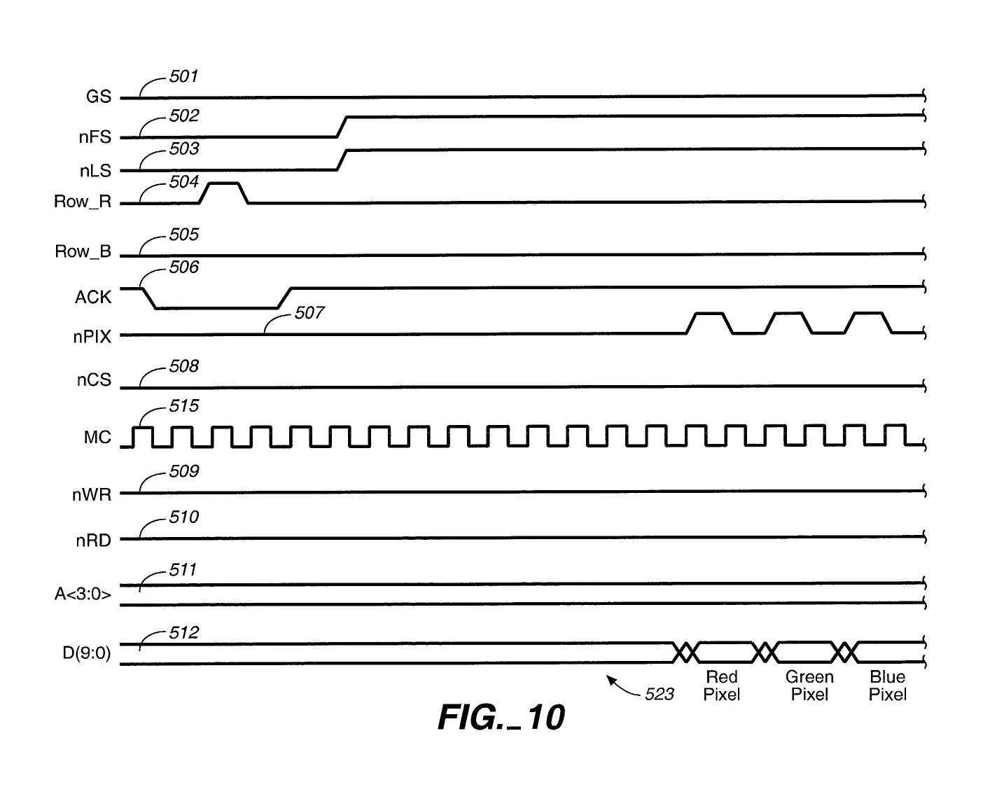

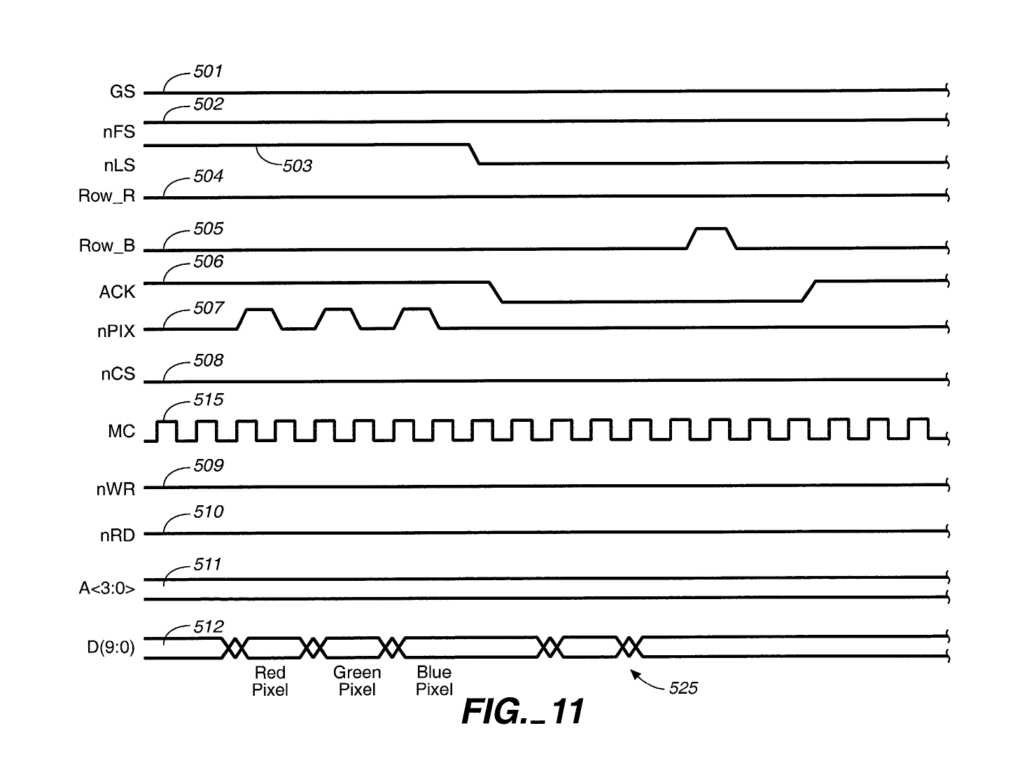

With reference to FIG. 11, the end of the row read and start of the next row blanking period 525 is shown. When the last pixel in the row is read out, the line sync signal 503 goes low and ends the row read. The acknowledgment signal 506 then goes low. To start the next row blanking period, the acknowledgment signal goes high and, then, the row blanking signal also goes high. With reference to FIG. 12, at the end of the frame 530, the frame sync and line sync signals 502, 503 both go low to end the frame.

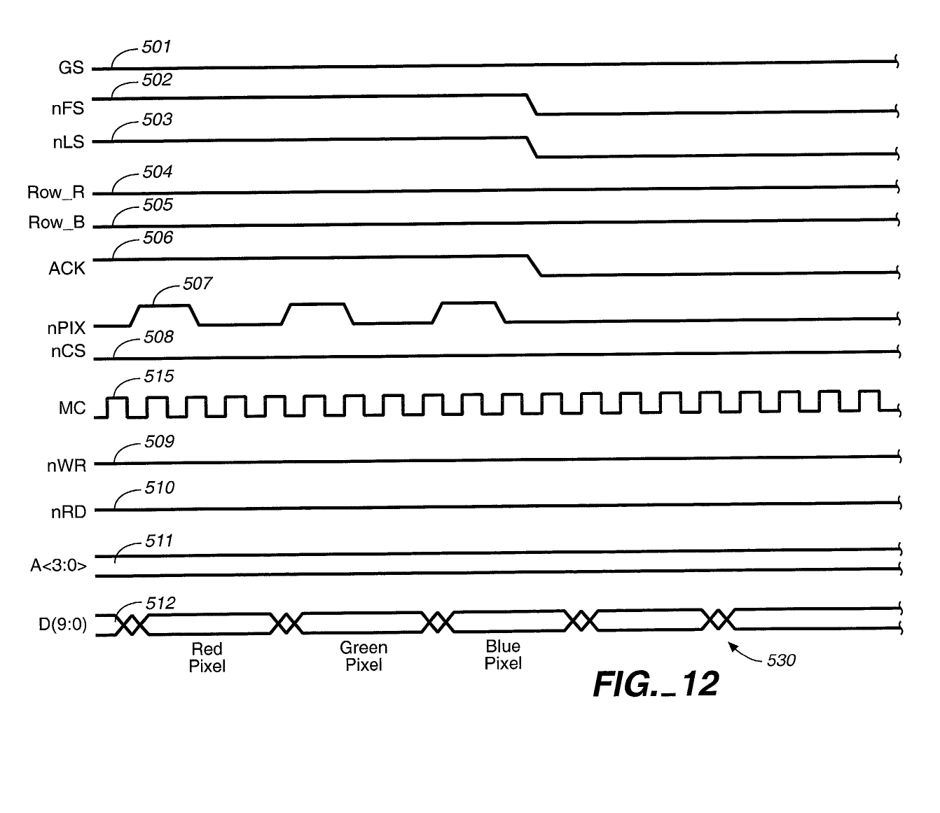

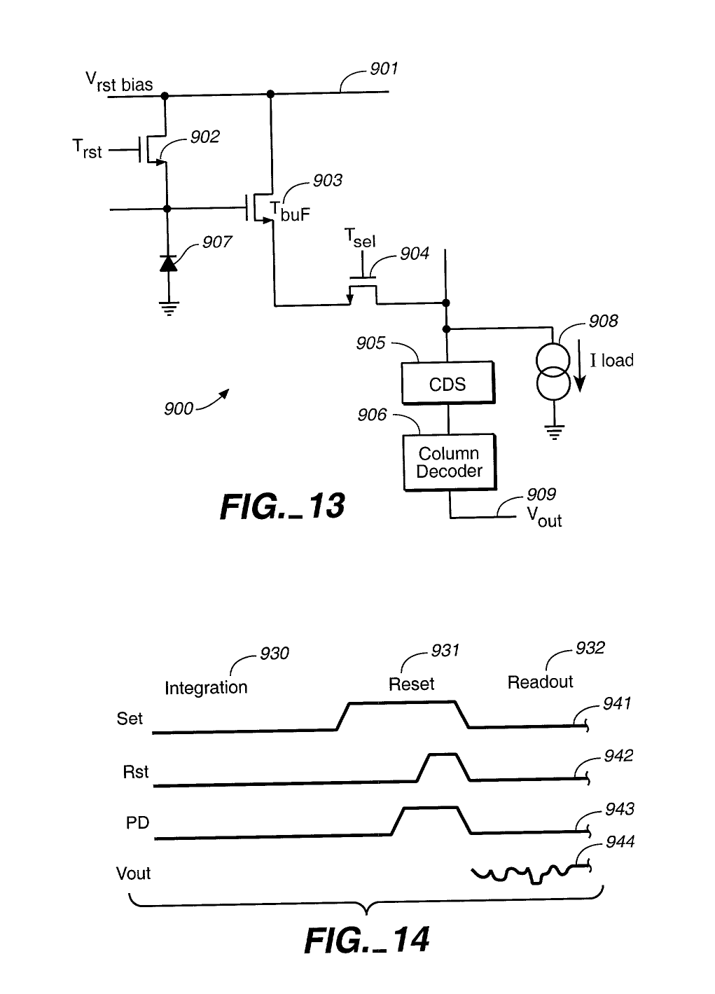

With reference to FIGS. 13 and 14, the pixel array 900 used in the image sensor of the present invention is shown. The pixel array can be any type of pixel array known in the prior art. The pixel array 900 used in the present invention is a three-transistor voltage mode photodiode design. The pixel has a reset transistor 902 having a drain terminal connected to the voltage reset bias line 901 and a gate terminal receiving the reset signal (Trst). Photodiode 907 has its anode connected to ground and cathode connected to the source terminal of the reset transistor 902. A buffer transistor 903 has a drain terminal connected to the reset bias line 901, and a gate terminal connected to the cathode of the photodiode 907. A select transistor 904 has its source terminal connected to the source terminal of the buffer transistor 903 and receives a select signal TSEL on its gate terminal. The drain terminal of the select transistor 904 is connected to the output voltage line 909. The voltage output line (VOUT) 909 is connected to a current source 908 and includes a column correlated double sampling (CDS) circuitry 905, as well as a column decoder 906.

FIG. 14 shows the timing diagrams for the select signal 941, reset signal 942, photodiode 943, and the output voltage 944. To initialize the pixel, the reset transistor 902, which is common with others across each row, is turned on and the photodiode active area charges up to the potential of the voltage reset bias line 901. When the reset transistor 902 is turned off to start the integration cycle 930, the photodiode 907 begins to discharge, which discharges intrinsic capacitors, and the resulting voltage level is buffer by the buffered transistor 903 through to the row select transistor 904. After integration is complete, the row select transistor 904 is turned on by activation of the select signal 941. The select transistor is common with other select transistors across the row. When the select transistor 904 is turned on, the pixel voltage is presented to the column read out bus 909. The photodiode will continue to integrate if still illuminated or until it is reset again by activating the reset signal (TRST) to reset transistor 902 in preparation for another exposure period. After reset, the read out cycle 932 begins and the voltage is read out of each column on the output voltage line 909.

1. An improved CMOS integrated imager system having an array of pixel areas with at least one control area, wherein said pixel areas include a plurality of light collecting elements which each receive light and store electronic information in an amount indicative of an amount of light received during an integration period, with the control area having an internal timing element, wherein the improvement comprises:
an interface for receiving a plurality of data, address, and control signals, said interface receiving a mode signal for setting the system in one of a first operating mode or a second operating mode characterized in that the first operating mode uses the internal timing element to control timing operation of the system and the second operating mode bypasses the internal timing element to control timing operation of the system.

2. The imager system of claim 1, wherein the control area includes a data bus, an address bus and a control bus electrically coupled to the interface and further includes a bypass multiplexer connected to the control bus, said multiplexer operating to interconnect the internal timing element to the control bus upon receipt of a first mode signal and operating to bypass the internal control element upon receipt of a second mode signal.

3. The imager system of claim 1, further including means for receiving timing signals from an external timing element when the system is operating in the second operating mode.

4. The imager system of claim 3, wherein the external timing element includes an external timing generator and a color recovery block.

5. The imager system of claim 3, wherein the external timing block includes a memory and a DMA interface block.

6. The imager system of claim 1, wherein the imager operates in the first operating mode when the interface is not connected to receive the mode signal.

7. A timing selector for a CMOS integrated imager comprising:
an onboard timing means, associated with a CMOS integrated imager, for providing standard timing signals to operate a clock circuit aboard the integrated imager;
an outboard logic circuit electrically connected to the CMOS integrated imager generating signals established by a user for establishing user defined timing signals for customized imager operation, and
a user interface allowing selection of the onboard timing means or outboard logic circuit.

8. The apparatus of claim 7, wherein the outboard logic circuit has means for generating clock signals bypassing the clock circuit.

9. The apparatus of claim 7, wherein the outboard logic circuit has means for generating clock signals using the clock circuit.
